(19) United States
(12) Patent Application Publication
(10) Pub. No.: US 2025/0304435 A1
(43) Pub. Date: Oct. 2, 2025

(54) CARTRIDGE WITH INTERNAL PILLAR

(71) Applicant: VueReal Inc., Waterloo (CA)

(72) Inventors: Gholamreza CHAJI, Kitchener (CA); Ehsanollah FATHI, Waterloo (CA)

(73) Assignee: VueReal Inc., Waterloo, ON (CA)

(21) Appl. No.: 18/864,692

(22) PCT Filed: May 9, 2023
(86) PCT No.: PCT/IB2023/054802

§ 371 Date: Nov. 11, 2024

Related U.S. Application Data
(60) Provisional application No. 63/339,935, filed on May 9, 2022.

(51) Int. Cl. B81C 3/00

(52) U.S. Cl. CPC B81C 3/001; B81C 2201/0191; B81C 2203/037; B81C 2203/0792

(57) ABSTRACT

The present invention discloses a process to transfer microdevices. The method involves coupling a microdevice to a donor substrate by a pillar layer, aligning the microdevice, bonding the microdevice and breaking the pillar layer with various scenarios. Also disclosed are various configurations of pillars within the structure such as edges and floating layers. Further, the method also discloses use and formation of nano-pillars to achieve the transfer of microdevices.

### CROSS-REFERENCE TO RELATED APPLICATION

This application claims the benefit of, and priority to, U.S. Provisional Patent Application No. 63/339,935 filed on May 9, 2022, which is hereby incorporated by reference herein in its entirety.

### FIELD OF THE INVENTION

The present disclosure relates to cartridge structure with an array of microdevices.

### SUMMARY

According to one embodiment, the invention relates to method to transfer microdevices, the method comprising, coupling a microdevice to a donor substrate by a pillar layer, aligning the microdevice with a system substrate, bonding the microdevice with the system substrate, breaking the pillar layer with the donor substrate and transferring the microdevice to the system substrate.

### BRIEF DESCRIPTION OF THE DRAWINGS

The foregoing and other advantages of the disclosure will become apparent upon reading the following detailed description and upon reference to the drawings.

FIG. 1A shows a microdevice connected to a substrate by a pillar.

FIG. 1B shows the microdevice aligned with a system substrate where there is a bonding layer in the system substrate.

FIG. 2A shows an embodiment of developing pillars.

FIG. 2B shows the new structure is bonded to a substrate.

FIG. 2C shows the original substrate is removed and the buffer/common layer is etched back or removed.

FIG. 2D shows a related embodiment where the interface between pillar and microdevice is modified.

FIG. 3A shows a structure bonded to a substrate.

FIG. 3B shows the original substrate is removed.

FIG. 4A highlights the formation of pillars.

FIG. 4B shows the structure after the substrate is removed.

FIG. 4C shows a layer that can be deposited on the surface of the device.

FIG. 4D shows the release/protection layer can be removed to leave a cavity under the device.

FIG. 4E shows the top view of the device with the floating layer coupled to a part of the pillar.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

The following description provides a microdevice structure and method to transfer microdevices.

In one embodiment, a cartridge structure comprises a substrate where an array of microdevices are coupled to the substrate through pillars. The backplane can be a substrate and can include other layers on either side of the substrate. The microdevices can be organic or inorganic optoelectronic devices, CMOS chiplet, MEMS, actuators, sensors or other devices. The pillars are formed at one edge of the microdevices. There can be a modified interface between the pillar and microdevices where the modification weakens the bonding between the pillar and the microdevices. The modified interface can be weakened through chemical processes such as solvent or acid exposure.

Another method to weaken the interface is the use of impurity in the interface. The impurity can be organic or inorganic materials.

In another case, the pillar can have a weak point that breaks under the pressure. The weak point can be developed by reducing the width of the pillar.

In one method the pillar is at the edge and dry etching is used to reduce the width of the pillar. Here the microdevice can be used as a mask for etching the pillar.

In one related case, the pillar is at the corner and so etching thin the pillar from both sides.

In one related case, the pillars are made of brittle materials.

In one related case, the pillars have an angle that is not a right angle (90) in reference to the surface of the microdevices. The pressure from the bonding of microdevices to a substrate will break the pillar very easily.

Another related embodiment is microdevices floating on a surface ready for transfer to a substrate. The embodiment also includes the process of developing the floating microdevices.

The related embodiment includes a microdevice connected to a floating layer where the floating layer is bonded to a pillar formed on a surface.

One case of developing microdevices floating on a surface is forming a pillar on surface bonding to a set of microdevices that are covered by a layer.

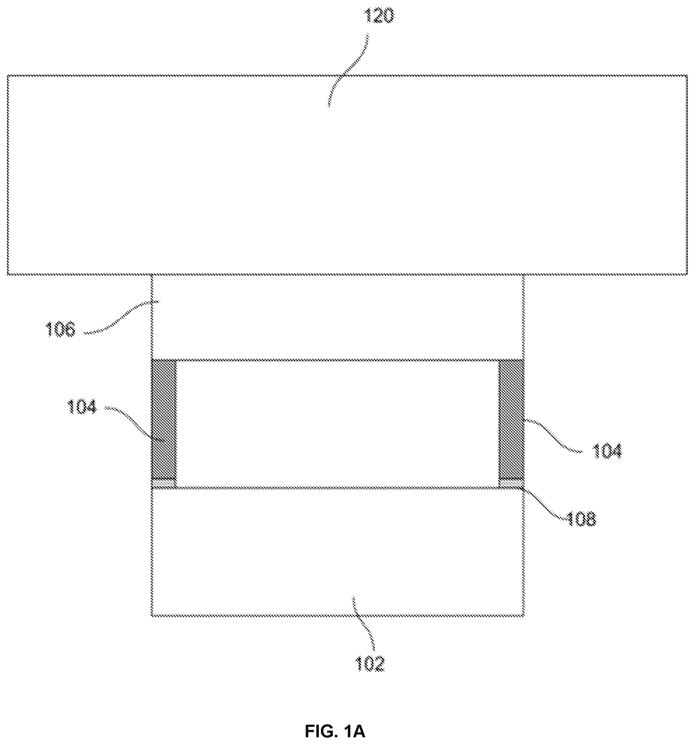

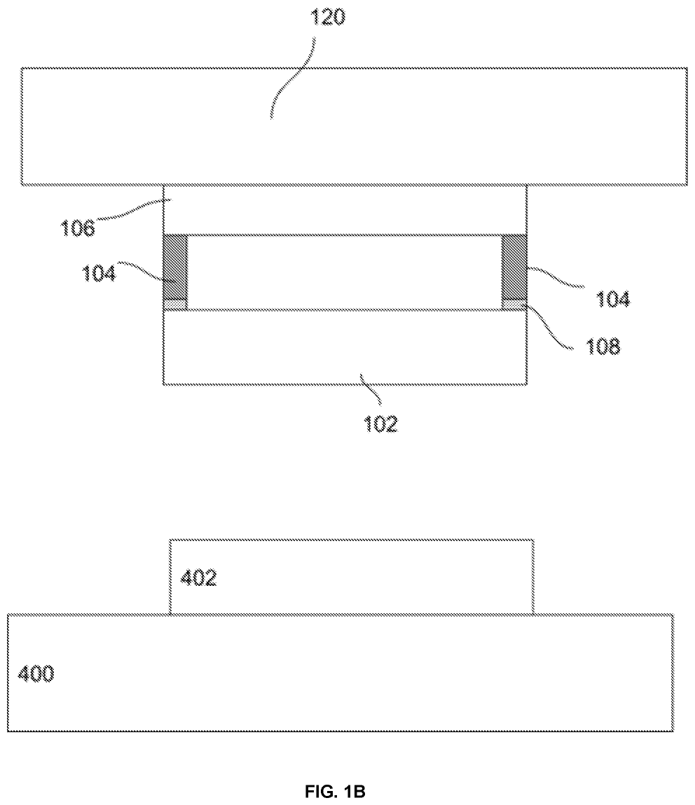

FIG. 1A shows a microdevice 102 connected to a substrate 120 by a pillar 104. There can be a buffer/bonding layer 106 between the pillar 104 and substrate 120. The pillar 104 can be the same material as the buffer/bonding layer 106. The interface 108 is between pillars and microdevices.

As shown in FIG. 1B, the microdevice can be aligned with a system substrate 400 where there is a bonding layer 402 in the system substrate 400. The microdevice 102 is bonded to the system substrate 400 and the donor substrate 120 and system substrate 400 are moved away. Either the process of bonding or separation of the two substrates can break the pillar layers or separate the pillar layer 104 from the microdevices 102 and leave the microdevice 102 into system substrate 400.

In one case, during the bonding process of a microdevice to the system substrate, pressure or temperature is used. Here, the pressure can be adjusted so that it breaks the pillars. In another related case, the temperature during the bonding is adjusted to reduce the adhesion between the pillar and the microdevice.

In another related case, the process of removing the system substrate and donor substrate from each other separates the pillar from the microdevice. Here the temperature can be used to reduce the adhesion between the pillar and the microdevices. The system substrate 400 can have driving circuits for the pixels. The bonding layer can be either bond pads or adhesive layers.

In one related embodiment, the interfaces 108 between pillars and microdevices are modified to enable the transfer. In one case, the interface provides adhesion force between the pillar and the microdevices. The adhesion can be modified by temperature or illumination to reduce the force. In another related embodiment, the temperature can decompose the material at the interfaces and so release the microdevices.

In other related cases, chemicals can be used to reduce the interfaces between microdevices and pillars. In one related embodiment, residual material can be formed at the interface. For example, a thin polymer layer can be formed on the surface that under temperature or with some chemical the adhesion of the microdevice to the pillar is reduced. Some implementations of embodiments in FIGS. 1A and 1B are explained in the next embodiments.

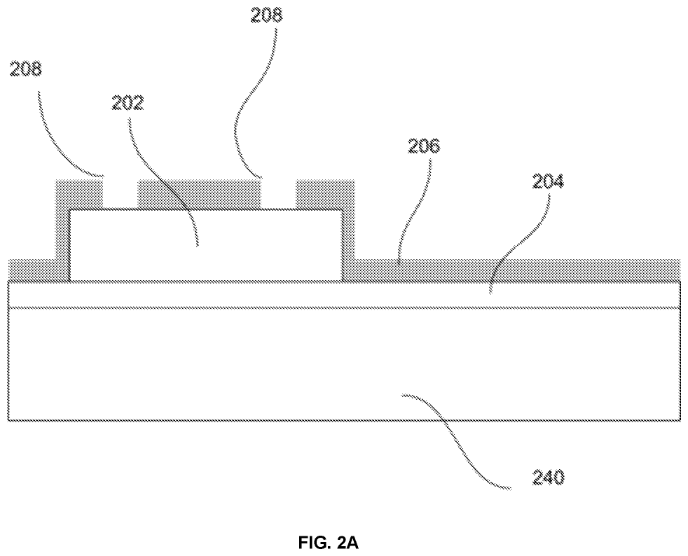

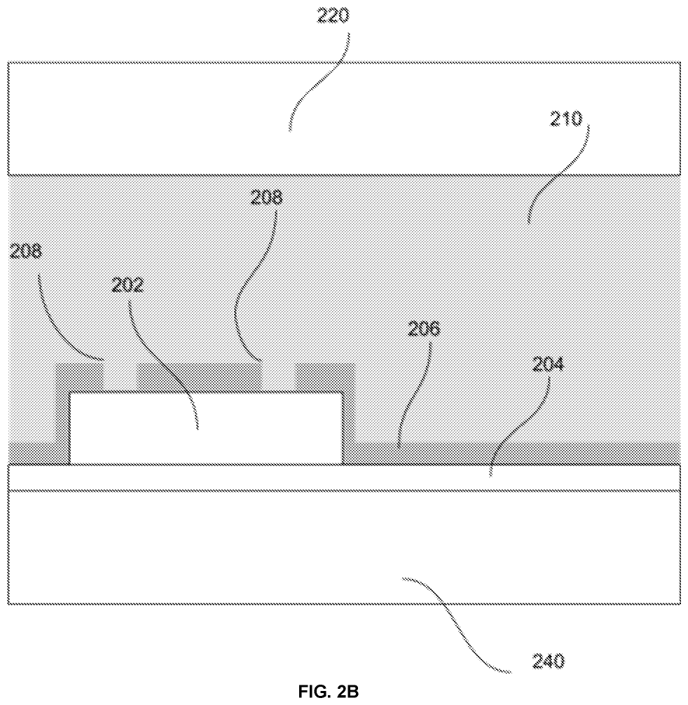

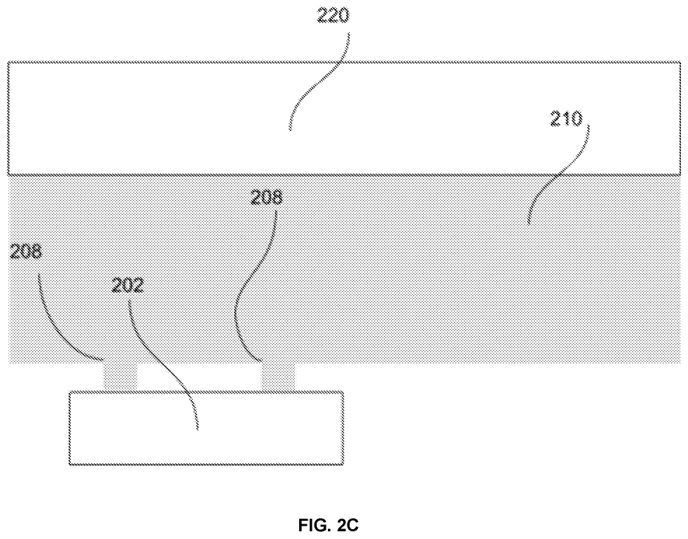

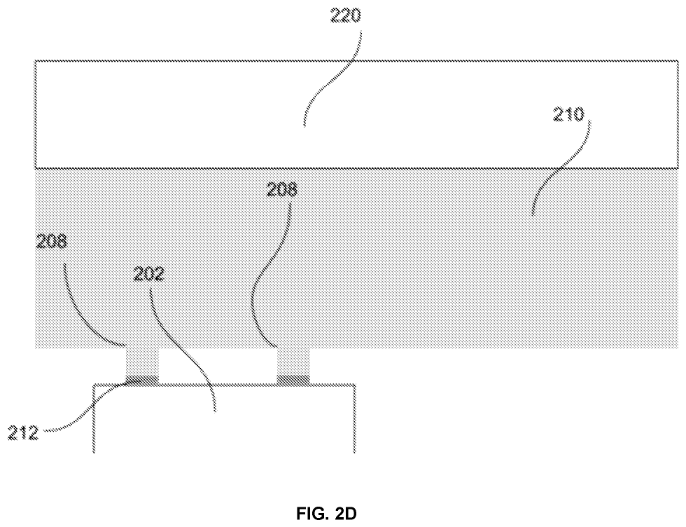

FIG. 2A shows a related embodiment of developing pillars. Here the microdevices are formed on a substrate 240. There can be a layer 204 between the microdevice 202 and substrate 240. The layer 204 can be part of microdevice 202. After the device is formed a protection layer 206 can be formed on top of the device 202. The protection layer 206 is etched to create openings 208. The etching can be dry etching or wet etching.

As shown in FIG. 2B, the new structure is bonded to a substrate 220. The bonding layer 210 can be made of different layers and materials. In one case, it can be BCB, polyamide, and other bonding materials.

As shown in FIG. 2C, the original substrate 240 can be removed and if a buffer/common layer 204 exists, it can be etched backed or removed. The protection layer 206 can be removed or modified. This process can be done through wet etching, light induced deformation, or other processes. The layer 210 can be etched back to clear the materials around the microdevice so that during the transfer the materials around the microdevice does not interfere with the system substrate. The etch back can be beyond the pillar base or near the microdevice 202 (Shown in FIG. 2C).

FIG. 2D highlights a related embodiment where the interface 212 between pillar 208 and microdevice 202 is modified. Here light, temperature, pressure or residual material is used to create a weather adhesion between the microdevice 202 and the pillar 212. Here, the adhesion between the pillar and microdevice is modified so that the microdevice can be separated from the donor substrate during the transfer with the bonding force between the microdevice and system substrate. The adhesion is modified by either applying pressure, temperature, or exposure to chemicals. In another related case, different material is used as the interface of the pillar so that it can be modified easier. The material can be a mix of adhesive or residual material that can be removed by exposure to chemicals.

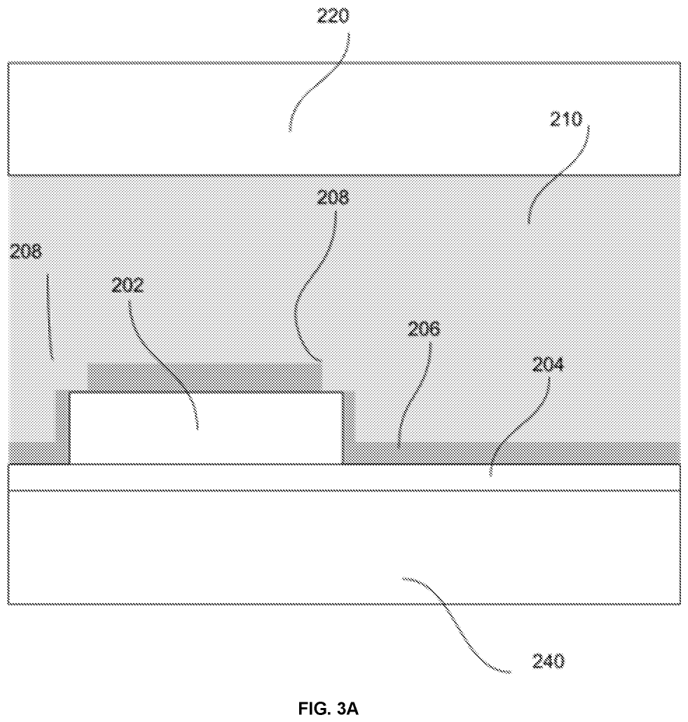

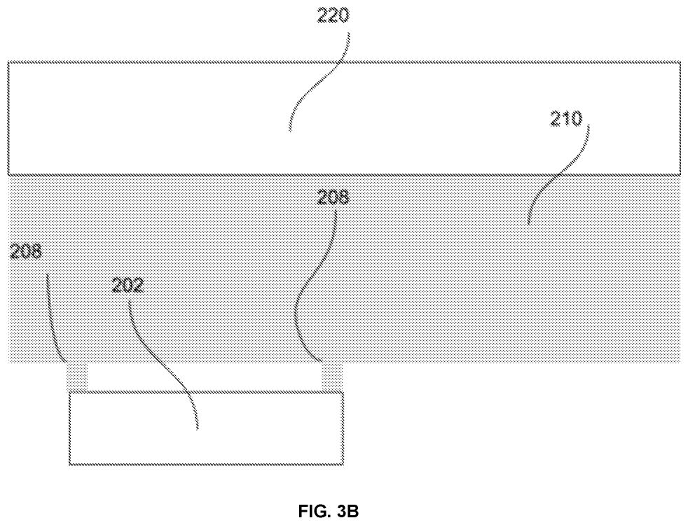

In another related embodiment, the pillar 208 is developed by an opening in the protective/release layer 206 on microdevice 202 at least on one edge of the microdevice. The process can be the same for embodiments of FIGS. 2A-2D and FIGS. 3A and 3B. Here, as shown in FIG. 3A, the structure is bonded to a substrate 220. There can be a structure on the substrate 220 such as planarization, soft material, and other structures.

As shown in FIG. 3B, the original substrate 240 is removed. The buffer/common layer can be etch backed. Here, the layer 210 is etched back. The microdevice can act as a mask (or another mask can be formed on top of the microdevice 202. The etch back of layer 210 can also etch the pillar and make it self-aligned with the edge of the device 202. The self-aligned process allows to reduce the size of pillar 208 beyond the original pattern formed by the opening of the protective/release layer. This can allow the size of the pillar to be smaller than the patterning capability. The pillar(s) 208 can be formed on the corner of the device 202 and as such from two sides it is self-aligned.

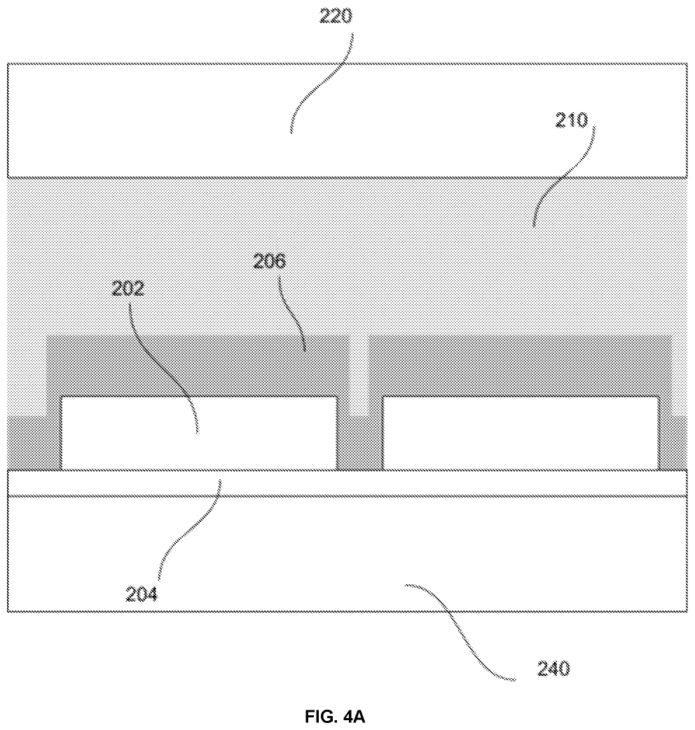

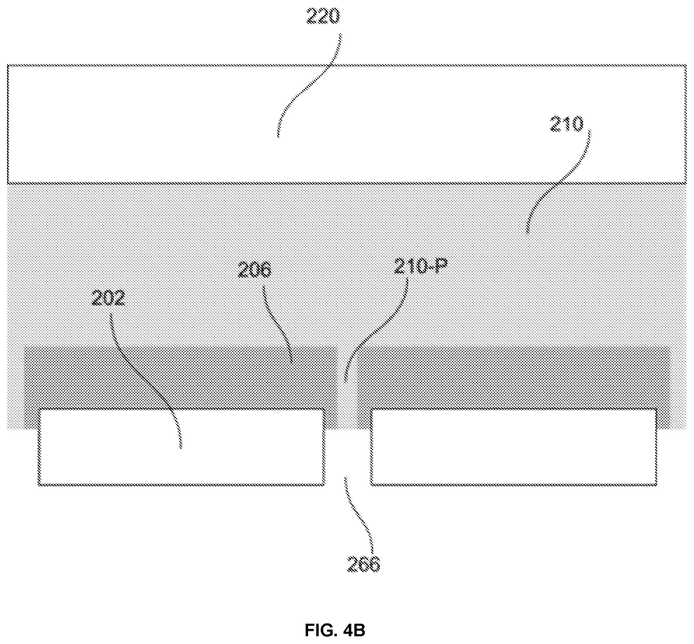

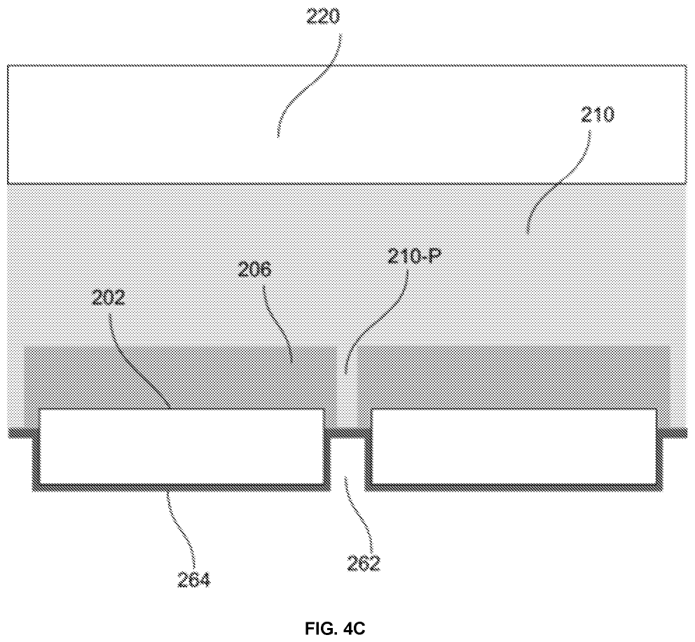

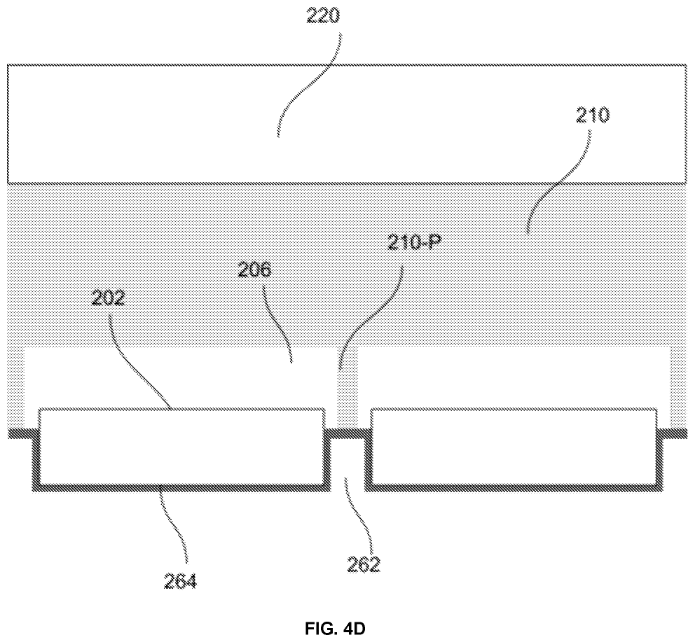

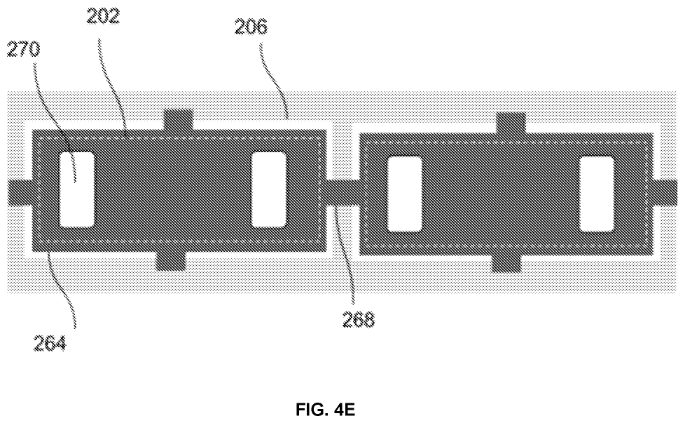

FIGS. 4A-4E shows microdevices floating on pillars formed on a surface. FIG. 4A highlights the formation of pillars. Here, after the microdevice 202 is formed on a substrate 240, a release/protection layer 206 is formed to cover the microdevice 202. There can be a buffer or common layer 204. After the formation of the protection layer 206, the structure is bonded to another substrate 220 using bonding layer 210. The bonding layer 210 can be multiple layers with different materials. The substrate 240 can be removed and the protection layer 206 can be removed from part of the surface exposing part of the pillars formed with the bonding layer(s) 210.

FIG. 4B shows the structure after the substrate 240 is removed, the common layer (buffer layer) 204 is removed and part of protection/release layer 206 is removed. And part of the pillar 210-P is exposed 266.

As shown in FIG. 4C, a layer 264 can be deposited on the surface of the device and it covers at least part of the device 202 sidewall and part of the exposed Pillar 210-P. The layer 264 can be patterned to provide access to the protection/release layer 206.

As shown in FIG. 4D, the release/protection layer 206 can be removed to leave a cavity under the microdevice and the microdevice stays floating with a layer 264 covering at least the top surface of the microdevice and is connected to part 268 of the pillar 210-P. The layer 264 can be patterned to provide access to some layers in the microdevice 202. Pads 270 can be formed on the floating layer 264 coupled to some of the layers in the device 202. There can be empty space 262 between the microdevices.

FIG. 4E shows the top view of the device with the floating layer 264 coupled to the part 268 of the pillar.

In a related embodiment, the pillar can form externally on a substrate and bonded to the microdevices. The pillar can be buried in a release layer and after bonding the release layer is removed. Or it can be bonded stand-alone to the microdevices.

In one related embodiment, more than one pillar can be bonded to the microdevice. Here the pillar can be a nano-pillar to easily disassociate from the microdevice. The nano-pillar can be distributed uniformly across the microdevice, or they can be clustered in small areas. The nano-pillar can be nanowire, nanotube or other form of one dimensional nanostructure. They can be formed on top of microdevices, or they can be formed on separate substrates and bonded to the microdevices.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method to transfer microdevices, the method comprising:
coupling a microdevice to a donor substrate by a pillar layer;
aligning the microdevice with a system substrate;
bonding the microdevice with the system substrate;
breaking the pillar layer with the donor substrate; and
transferring the microdevice to the system substrate.

2. A method of claim 1, wherein during the bonding process of microdevice to the system substrate pressure or temperature is used.

3. A method of claim 2, wherein the pressure is adjusted to break the pillar layer.

4. A method of claim 2, wherein the temperature during the bonding is adjusted to reduce the adhesion between the pillar and the microdevice.

5. The method of claim 1, wherein there is a bonding/buffer layer between a pillar and the donor substrate.

6. The method of claim 5, wherein the pillar is of the same material as the buffer/bonding layer.

7. The method of claim 1, wherein there is another bonding layer in the system substrate, the system substrate has driving circuits for pixels and the bonding layer has either bond pads or adhesive layers.

8. The method of claim 1, wherein an interface between the pillar layer and microdevices is modified to enable the transfer wherein a residual material is formed at the interface.

9. The method of claim 8, wherein the interface provides an adhesion force between the pillar and the microdevices.

10. The method of claim 9, wherein the adhesion is modified by temperature or illumination to reduce the force.

11. The method of claim 10, wherein the temperature decomposes the material at the interfaces releasing the microdevices.

12. The method of claim 9, wherein a chemical can be used to reduce the interface between microdevice and pillar.

13. The method of claim 8, wherein a different material that is a mix of adhesive or residual material, is used as the interface of the pillar that is removed by exposure to chemicals.

14. The method of claim 8, wherein a thin polymer layer is formed on a surface, that under a temperature or with a chemical the adhesion of the microdevice to the pillar is reduced.

15. The method of claim 1, wherein microdevices are formed on a first substrate, with a first layer between the microdevices and the first substrate, wherein the first layer is part of the microdevice.

16. The method of claim 15, wherein a protection layer is formed on top of the microdevice.

17. The method of claim 16, wherein the protection layer is etched to create openings.

18. The method of claim 17, wherein the microdevice is bonded to a second substrate via a first bonding layer.

19. The method of claim 18, wherein the first bonding layer is made of different layers and materials.

20. The method of claim 19, wherein the first bonding layer is made of BCB, or polyamide.

21. The method of claim 18, wherein the first substrate and the first layer are removed.

22. The method of claim 21, wherein the protection layer is removed or modified, and the first bonding layer is etched back beyond a pillar base.

23. The method of claim 15, wherein the first substrate is removed, and a buffer/common layer is etched back and the microdevice acts as a mask.

24. The method of claim 17, wherein the protection layer is removed or modified through wet etching or light induced deformation.

25. The method of claim 17, wherein the pillar is developed in an opening in the protective/release layer on the microdevice on at least one edge of the device.

26. The method of claim 25, wherein the interface between the pillar and microdevice is modified.

27. The method of claim 26, wherein a light, a temperature, a pressure, or the residual material is used to create a weaker adhesion between the microdevice and the pillar.

28. The method of claim 27, wherein the adhesion between the pillar and microdevice is modified so that the microdevice is separated from the donor substrate during the transfer with the bonding force between the microdevice and system substrate.

29. The method of claim 28, wherein the adhesion is modified by either applying pressure, temperature, or exposure to chemicals.

30. The method of claim 26, wherein the material of the interface is a mix of adhesive or residual material that is removed by exposure to chemicals.

31. The method of claim 25, wherein the bonding layer is bonded to the second substrate.

32. The method of claim 31, wherein the donor substrate is removed, and the bonding layer is etched back making the microdevice act as the mask.

33. The method of claim 32, wherein the etch back of the bonding layer also etches the pillar and makes it self-aligned with the edge of the microdevice.

34. The method of claim 32, wherein the self-alignment reduces a size of pillar beyond an original pattern formed by the opening of the protective/release layer allowing the size of the pillar to be smaller than the patterning capability.

35. The method of claim 32, wherein the pillars are formed on the corner of the microdevice.

36. The method of claim 16, wherein the first substrate is removed, and the protection layer is removed from part of the surface exposing part of the pillars formed with the bonding layer.

37. The method of claim 36, wherein a floating layer is deposited on the surface of the microdevice covering at least part of the microdevice sidewall and part of the exposed pillar.

38. The method of claim 37, where the floating layer is patterned to provide access to the protection/release layer.

39. The method of claim 38, wherein the release/protection layer is removed to leave a cavity under the device and the device stays floating with the layer covering at least a top surface of the device and is connected to a part of the exposed pillar.

40. The method of claim 39, wherein the floating layer is patterned to provide access to the release/protection layers in the microdevice.

41. The method of claim 40, wherein pads are formed on the floating layer coupled to some of the layers in the device.

42. The method of claim 40, wherein there are empty spaces between the microdevices.

43. The method of claim 32, wherein the pillar is formed externally on a substrate and bonded to the microdevices.

44. The method of claim 43 wherein the pillar is buried in a release layer and after bonding the release layer is removed or it is bonded as a stand-alone to the microdevices.

45. The method of claim 43, where more than one pillar is bonded to the microdevice.

46. The method of claim 45, wherein the pillars are nano-pillars to easily disassociate from the microdevice.

47. The method of claim 46, wherein the nano-pillars are distributed uniformly across the microdevice or clustered in small areas.

48. The method of claim 46, wherein the nano-pillars are nanowire, nanotube or other forms of one dimensional nanostructure.

49. The method of claim 47, wherein the nano-pillars are formed on top of microdevices or formed on separate substrates and bonded to the microdevices.
